(19) United States
(12) Patent Application Publication
(10) Pub. No.: US 2025/0380525 A1
(43) Pub. Date: Dec. 11, 2025

(54) IMAGE SENSOR

(71) Applicant: Samsung Electronics Co., Ltd., Suwon-si (KR)

(72) Inventors: Junoh KIM, Suwon-si (KR); HAEWON LEE, Suwon-si (KR)

(21) Appl. No.: 19/190,999

(22) Filed: Apr. 28, 2025

(30) Foreign Application Priority Data
Jun. 5, 2024 (KR) 10-2024-0073643

(51) Int. Cl. H10F 39/00; H10F 39/18

(52) U.S. Cl. CPC H10F 39/807; H10F 39/182

(57) ABSTRACT

An image sensor is provided. The image sensor may include a semiconductor substrate of a first conductivity type including a plurality of pixel regions, a pixel separation structure disposed between the pixel regions and vertically penetrating the semiconductor substrate, the pixel separation structure including a buried pattern and a sidewall insulating pattern between a sidewall of the buried pattern and the semiconductor substrate, photoelectric conversion regions provided in each of the pixel regions and including impurities of a second conductivity type, and a charge drain region of the second conductivity type provided in the semiconductor substrate, the charge drain region contacting an interface region between the sidewall insulating pattern and the semiconductor substrate. The buried pattern includes a semiconductor material doped with impurities of the second conductivity type.

### CROSS-REFERENCE TO RELATED APPLICATIONS

This U.S. non-provisional patent application claims priority under 35 U.S.C. § 119 to Korean Patent Application No. 10-2024-0073643 filed on Jun. 5, 2024, in the Korean Intellectual Property Office, the entire contents of which are hereby incorporated by reference.

### BACKGROUND

The inventive concept relates to an image sensor, and more specifically, relates to an image sensor with improved electrical and optical characteristics.

An image sensor converts photonic images into electrical signals. Recent advances in computer and communication industries have led to strong demand for high performance image sensors in various consumer electronic devices, such as digital cameras, camcorders, personal communication systems (PCS), game devices, security cameras, and medical micro-cameras.

Image sensors may be categorized as charge coupled device (CCD) image sensors or complementary metal-oxide-semiconductor (CMOS) image sensors. CMOS image sensors may be simply driven. A CMOS image sensor may be realized (“implemented”) as a single, individual chip on which a signal processing circuit and an image sensing portion are integrated.

Thus, a size of the CMOS image sensor may be reduced. Moreover, a CMOS image sensor may have very low power consumption to be configured to be easily applied to a product having a limited battery capacity. Furthermore, a CMOS image sensor may have high image sensing resolution based on the development of a CMOS technique. Accordingly, CMOS image sensors are widely used in various fields.

### SUMMARY

Some embodiments of the disclosure provide an image sensor with improved electrical and optical characteristics.

The object of the disclosure is not limited to that mentioned above, and other objects which have not been mentioned above will be clearly understood by those skilled in the art from the description below.

An image sensor according to some embodiments of the inventive concept may include a semiconductor substrate of a first conductivity type including a plurality of pixel regions, a pixel separation structure disposed between the pixel regions and vertically penetrating the semiconductor substrate, the pixel separation structure including a buried pattern and a sidewall insulating pattern between a sidewall of the buried pattern and the semiconductor substrate, photoelectric conversion regions provided in each of the pixel regions and including impurities of a second conductivity type, and a charge drain region of the second conductivity type provided in the semiconductor substrate, the charge drain region contacting an interface region between the sidewall insulating pattern and the semiconductor substrate. The buried pattern includes a semiconductor material doped with impurities of the second conductivity type.

An image sensor according to some embodiments of the inventive concept may include a semiconductor substrate of a first conductivity type, a pixel separation structure disposed in the semiconductor substrate and defining a pixel region, the pixel separation structure including a buried pattern and a sidewall insulating pattern between a sidewall of the buried pattern and the semiconductor substrate, and a photoelectric conversion region of a second conductivity type provided in the semiconductor substrate of the pixel region. In the pixel separation structure, the buried pattern includes a material having a work function smaller than that of the semiconductor substrate.

An image sensor according to some embodiments of the inventive concept may include a semiconductor substrate of a first conductivity type having first and second surfaces facing away from each other, a pixel separation structure disposed in the semiconductor substrate and defining a plurality of pixel regions, the pixel separation structure including a buried pattern including a semiconductor material doped with impurities of a second conductivity type, and a sidewall insulating pattern between a sidewall of the buried pattern and the semiconductor substrate, a charge drain region of the second conductivity type in contact with an interface region between the sidewall insulating pattern and the semiconductor substrate in the semiconductor substrate, photoelectric conversion regions provided in each of the pixel regions and including impurities of the second conductivity type, a floating diffusion region having impurities of the second conductivity type provided in the semiconductor substrate, transfer gate electrodes disposed between the photoelectric conversion regions and the floating diffusion region, a ground impurity region provided in each of the pixel regions and including impurities of the first conductivity type, a plurality of micro lenses disposed on the second surface of the semiconductor substrate and provided respectively in the pixel regions, and color filters disposed between the micro lenses and the second surface of the semiconductor substrate and provided to each of the pixel regions.

Specific details of other embodiments are included in the detailed description and drawings.

### BRIEF DESCRIPTION OF DRAWINGS

Example embodiments will be more clearly understood from the following brief description taken in conjunction with the accompanying drawings. The accompanying drawings represent non-limiting, example embodiments as described herein.

FIG. 1 is a block diagram of an image sensor according to embodiments of the inventive concept.

FIGS. 2A and 2B are circuit diagrams of unit pixels of an image sensor according to embodiments of the inventive concept.

FIG. 3 is a plan view showing a portion of an image sensor according to embodiments of the inventive concept.

FIG. 4A is a cross-sectional view of an image sensor according to embodiments of the inventive concept, taken along line I-I′ of FIG. 3.

FIG. 4B is a cross-sectional view of an image sensor according to embodiments of the inventive concept, taken along line II-II′ of FIG. 3.

FIG. 5 is an enlarged view of portion ‘PA’ of FIG. 4B.

FIG. 6 is an energy band diagram in the cross section A-A′ of FIG. 5.

FIG. 7A is a plan view showing a portion of an image sensor according to embodiments of the inventive concept.

FIG. 7B is a plan view showing a portion of an image sensor according to embodiments of the inventive concept.

FIG. 8A is an enlarged view of portion ‘PB’ of FIG. 7A.

FIG. 8B is an enlarged view of portion ‘PC’ of FIG. 7B.

FIG. 9 is a plan view showing a portion of an image sensor according to embodiments of the inventive concept.

FIG. 10 is a cross-sectional view of an image sensor according to embodiments of the inventive concept, taken along line I-I′ of FIG. 3.

FIG. 11 is a schematic plan view of an image sensor including a semiconductor device according to embodiments of the inventive concept.

FIGS. 12 and 13 are cross-sectional views of an image sensor according to embodiments of the inventive concept, showing a cross-section taken along line III-III′ of FIG. 11.

### DETAILED DESCRIPTION

Hereinafter, an image sensor according to embodiments of the inventive concept will be described in detail with reference to the drawings.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Terms such as “same,” “equal,” “planar,” or “coplanar,” as used herein when referring to orientation, layout, location, shapes, sizes, compositions, amounts, or other measures do not necessarily mean an exactly identical orientation, layout, location, shape, size, composition, amount, or other measure, but are intended to encompass nearly identical orientation, layout, location, shapes, sizes, compositions, amounts, or other measures within typical variations that may occur resulting from conventional manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first”) in a particular claim may be described elsewhere with a different ordinal number (e.g., “second”) in the specification or another claim.

Spatially relative terms, such as “beneath,” “below,” “lower,” “above,” “upper,” “top,” “bottom,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

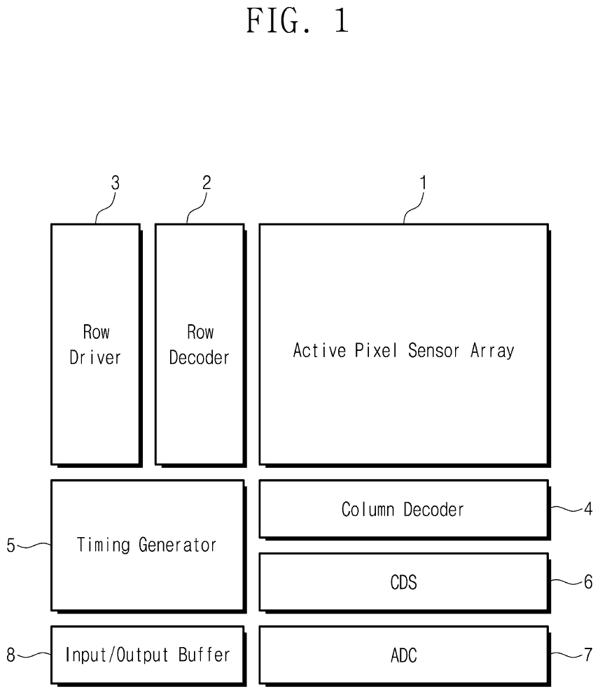

FIG. 1 is a block diagram of an image sensor according to embodiments of the inventive concept.

Referring to FIG. 1, an image sensor may include an active pixel sensor array 1, a row decoder 2, a row driver 3, a column decoder 4, a timing generator 5, a correlated double sampler (CDS) 6, an analog-to-digital converter (ADC) 7, and an input/output buffer 8.

The active pixel sensor array 1 may include a plurality of two-dimensionally arranged unit pixels, each of which is configured to convert optical signals into electrical signals. The active pixel sensor array 1 may be driven by a plurality of driving signals such as a pixel selection signal, a reset signal, and a charge transfer signal from the row driver 3. The converted electrical signals may be provided for the correlated double sampler 6.

The row driver 3 may provide the active pixel sensor array 1 with several driving signals for driving several unit pixels in accordance with a decoded result obtained from the row decoder 2. When the unit pixels are arranged in a matrix shape, the driving signals may be provided for respective rows.

The timing generator 5 may provide the row and column decoders 2 and 4 with timing and control signals.

The correlated double sampler (CDS) 6 may receive the electrical signals generated in the active pixel sensor array 1, and may hold and sample the received electrical signals. The correlated double sampler 6 may perform a double sampling operation to sample a specific noise level and a signal level of the electrical signal, and then output a difference level corresponding to a difference between the noise and signal levels.

The analog-to-digital converter (ADC) 7 may convert analog signals, which correspond to the difference level received from the correlated double sampler 6, into digital signals and then output the converted digital signals.

The input/output buffer 8 may latch the digital signals and then sequentially output the latched digital signals to an image signal processing unit (not shown) in response to the decoded result obtained from the column decoder 4.

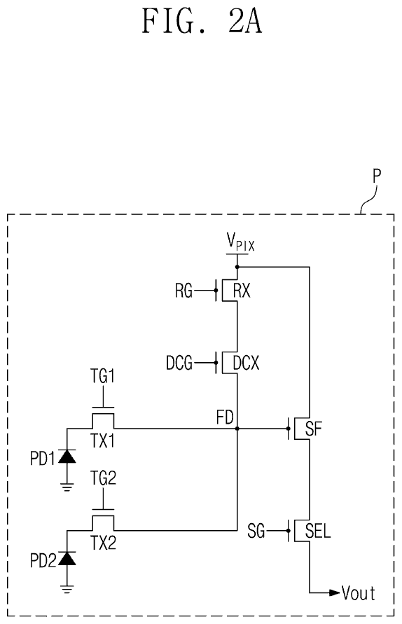

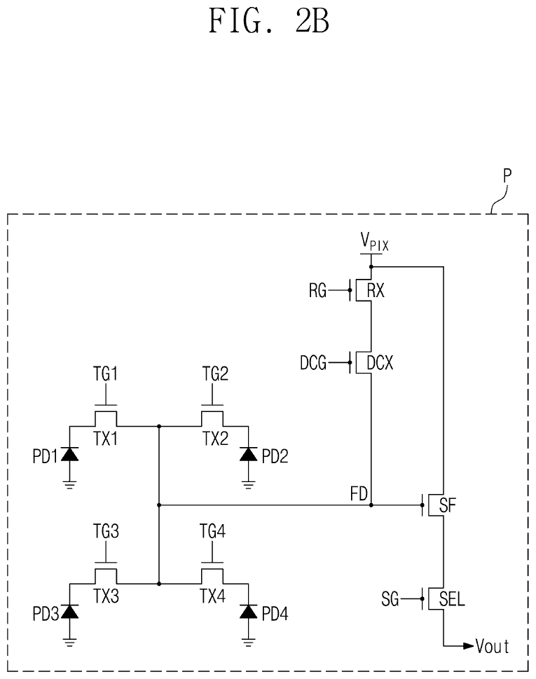

FIGS. 2A and 2B are circuit diagrams of unit pixels of an image sensor according to embodiments of the inventive concept.

Referring to FIG. 2A, the unit pixel P may include first and second photoelectric conversion elements PD1 and PD2, first and second transfer transistors TX1 and TX2, and a floating diffusion region FD (or a charge detection node) commonly connected to the first and second transfer transistors TX1 and TX2.

The pixel transistors may include a reset transistor RX, a source follower transistor SF, a selection transistor SEL, and a dual conversion gain transistor DCX. In the embodiments, each unit pixel P may include four pixel transistors, but the inventive concept is not limited thereto, and the number of pixel transistors in each unit pixel P may be variously changed.

In detail, the first and second photoelectric conversion elements PD1 and PD2 may generate and accumulate charges corresponding to incident light. The first and second photoelectric conversion elements PD1 and PD2 may be, for example, a photo diode, a photo transistor, a photo gate, and a pinned photo diode (PPD) and combinations thereof.

The first and second transfer transistors TX1 and TX2 may transfer charges accumulated in the first and second photoelectric conversion elements PD1 and PD2 to the floating diffusion region FD. The first and second transfer transistors TX1 and TX2 may be controlled by the first and second transfer signals TG1 and TG2. The first and second transfer transistors TX1 and TX2 may share a floating diffusion region FD.

The floating diffusion region FD may receive charges generated in the first or second photoelectric conversion elements PD1 and PD2 and may store the charges cumulatively. The source follower transistor SF may be controlled depending on the amount of photocharges accumulated in the floating diffusion region FD.

The reset transistor RX may periodically reset charges accumulated in the floating diffusion region FD in response to a reset signal applied to the reset gate electrode RG. In detail, a drain terminal of the reset transistor RX may be connected to the double conversion gain transistor DCX, and a source terminal thereof may be connected to a pixel power voltage V_{PIX}. When the reset transistor RX and the double conversion gain transistor DCX are turned on, the pixel power voltage V_{PIX} is transferred to the floating diffusion region FD. Accordingly, the charges accumulated in the floating diffusion region FD may be discharged and the floating diffusion region FD may be reset.

The double conversion gain transistor DCX may be connected between the floating diffusion region FD and the reset transistor RX. The double conversion gain transistor DCX may be connected in series with the reset transistor RX. The dual conversion gain transistor DCX may change conversion gain of the unit pixel P by changing the capacitance of the floating diffusion region FD in response to the double conversion gain control signal.

Specifically, when acquiring an image, low-intensity and high-intensity light may be incident on the pixel array at the same time, or strong light and weak light may be incident on the pixel array at the same time. Accordingly, the conversion gain of each pixel may be variously changed in response to the incident light. For example, when the double conversion gain transistor DCX is turned off, the unit pixel P may have a first conversion gain, and when the double conversion gain transistor DCX is turned on, the unit pixel P may have a second conversion gain that is greater than the first conversion gain. Therefore, depending on the operation of the dual conversion gain transistor DCX, different conversion gains may be provided in a first conversion gain mode (or a high brightness mode) and a second conversion gain mode (or a low brightness mode).

When the double conversion gain transistor DCX is turned off, a capacitance of the floating diffusion region FD may have a first capacitance. When the double conversion gain transistor DCX is turned on, a capacitance of the floating diffusion region FD may have a second capacitance that is greater than the first capacitance. When the dual conversion gain transistor DCX is turned on, a capacitance of the floating diffusion region FD may increase to reduce the conversion gain, and when the dual conversion gain transistor DCX is turned off, a capacitance of the floating diffusion region FD may decrease to increase the conversion gain.

The source follower transistor SF may be a source follower buffer amplifier that generates source-drain current in proportion to the amount of charge in the floating diffusion region FD input to the source follower gate electrode. The source follower transistor SF amplifies a potential change in the floating diffusion region FD and outputs the amplified signal to the output line Vout through the selection transistor SEL. A source terminal of the source follower transistor SF may be connected to the pixel power voltage V_{PIX}, and a drain terminal of the source follower transistor SF may be connected to a source terminal of the selection transistor SEL.

The selection transistor SEL may select unit pixels P to be read row by row. When the selection transistor SEL is turned on by the selection signal SG applied to the selection gate electrode, an electrical signal output to a drain electrode of the source follower transistor SF may be output to the output line Vout.

Referring to FIG. 2B, the unit pixel P may include first, second, third, and fourth photoelectric conversion elements PD1, PD2, PD3, and PD4, first, second, third, and fourth transfer transistors TX1, TX2, TX3, and TX4, and a floating diffusion region FD. Additionally, the unit pixel P may include four pixel transistors RX, DCX, SF, and SEL, similar to the embodiment of FIG. 2A.

The first to fourth transfer transistors TX1, TX2, TX3, and TX4 may share one floating diffusion region FD. The transfer gate electrodes of the first to fourth transfer transistors TX1, TX2, TX3, and TX4 may be controlled by the first to fourth transfer signals TG1, TG2, TG3, and TG4, respectively.

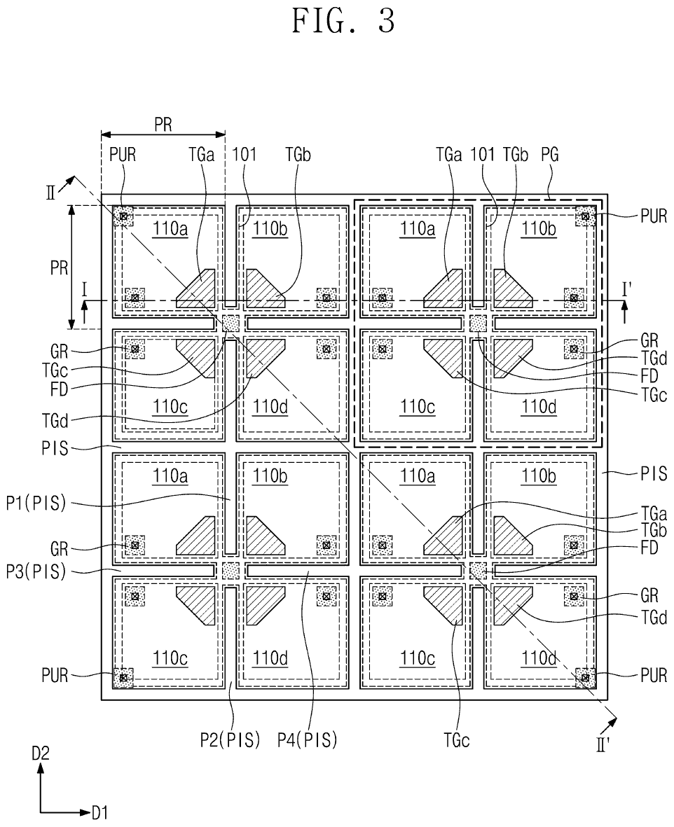

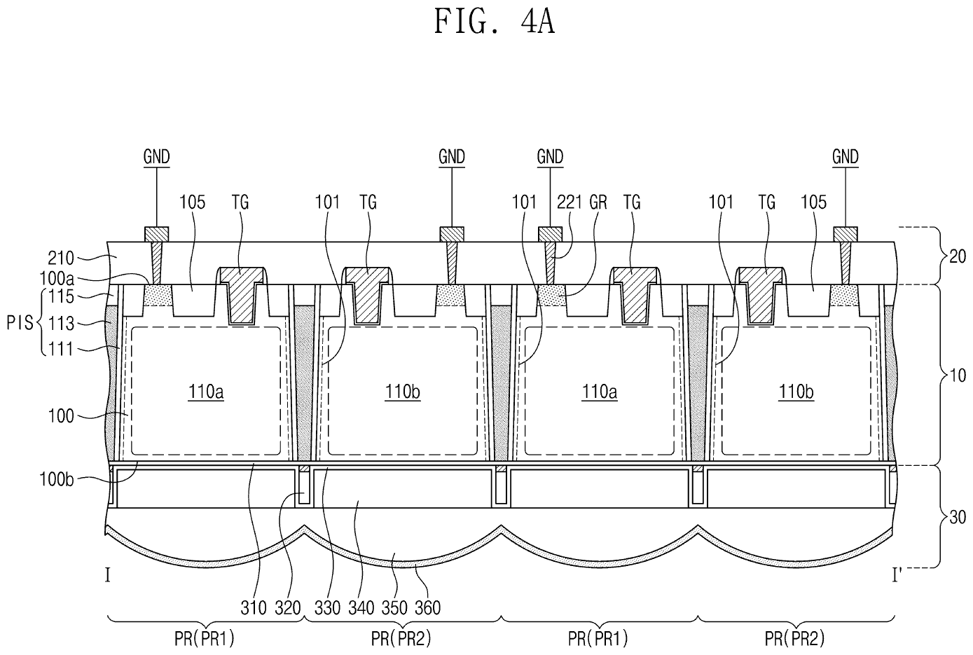

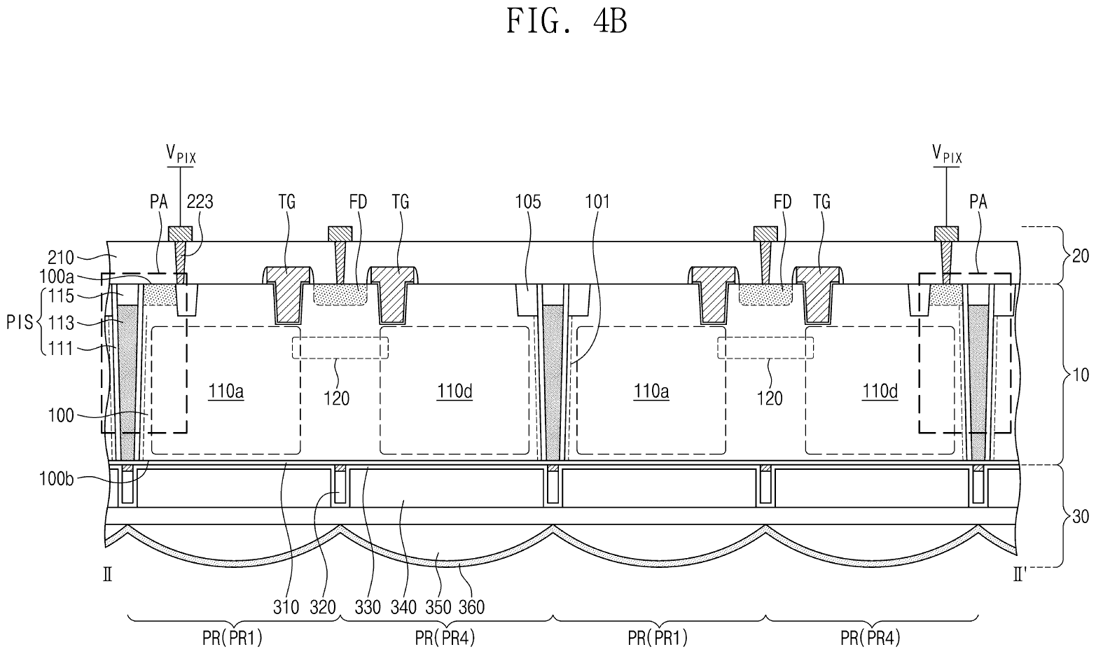

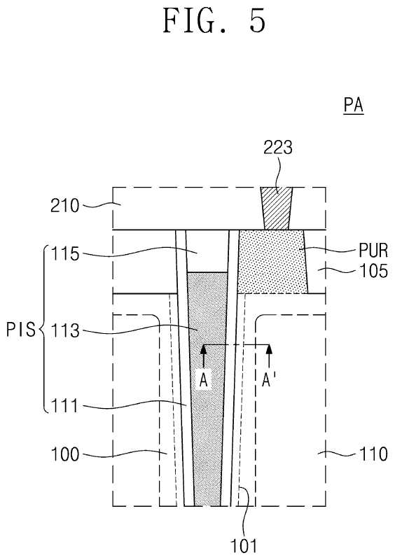

FIG. 3 is a plan view showing a portion of an image sensor according to embodiments of the inventive concept. FIG. 4A is a cross-sectional view of an image sensor according to embodiments of the inventive concept, taken along line I-I′ of FIG. 3. FIG. 4B is a cross-sectional view of an image sensor according to embodiments of the inventive concept, taken along line II-II′ of FIG. 3. FIG. 5 is an enlarged view of portion ‘PA’ of FIG. 4B.

Referring to FIGS. 3, 4A, and 4B, an image sensor according to embodiments of the inventive concept may include a photoelectric conversion circuit layer 10, a pixel circuit layer 20, a light transmission layer 30, and a logic circuit layer (not shown).

The photoelectric conversion circuit layer 10 may be disposed between the pixel circuit layer 20 and the light transmission layer 30 when viewed in a vertical perspective view. The photoelectric conversion circuit layer 10 may include a semiconductor substrate 100, a pixel separation structure PIS, photoelectric conversion regions 110a, 110b, 110c, and 110d, transfer gate electrodes TGa, TGb, TGc, and TGd, and floating diffusion regions FD.

More specifically, the semiconductor substrate 100 may have a first surface 100a (or a front surface) and a second surface 100b (or a back surface) that face away from each other. The semiconductor substrate 100 may be a substrate in which a first conductivity type epitaxial layer is formed on a first conductivity type (e.g., p-type) bulk silicon substrate, and during the manufacturing process of the image sensor, the bulk silicon substrate may be removed, leaving only the p-type epitaxial layer. Alternatively, the semiconductor substrate 100 may be a bulk semiconductor substrate including wells of the first conductivity type.

The semiconductor substrate 100 may include a plurality of pixel groups PG. Each of the pixel groups PG may include at least 4, 8, or 16 pixel regions PR. In each pixel group PG, pixel regions PR may be arranged in a matrix form in first and second directions D1 and D2 that intersect each other.

For example, the pixel regions PR may include first and second pixel regions PR1 and PR2 arranged in the first direction D1, a third pixel region PR3 adjacent to the first pixel region PR1 in the second direction D2 intersecting the first direction D1, and a fourth pixel region PR4 adjacent to the second pixel region PR2 in the second direction D2.

Photoelectric conversion regions 110a, 110b, 110c, and 110d doped with second conductivity type impurities may be provided in the semiconductor substrate 100 of the pixel regions PR. In more detail, first to fourth photoelectric conversion regions 110a to 110d may be provided in the first to fourth pixel regions PR1 to PR4, respectively.

The first to fourth photoelectric conversion regions 110a to 110d may generate photocharges in proportion to the intensity of incident light. The first to fourth photoelectric conversion regions 110a to 110d may be doped with impurities having a second conductivity type (e.g., n-type) opposite to the first conductivity type of the semiconductor substrate 100 by implanting ions into the semiconductor substrate 100. Photodiodes may be constituted by a junction between the semiconductor substrate 100 of the first conductivity type and the first to fourth photoelectric conversion regions 110a to 110d of the second conductivity type.

According to some embodiments, the first to fourth photoelectric conversion regions 110a to 110d may have a potential gradient between the first surface 100a and the second surface 100b of the semiconductor substrate 100 such that there is a difference in impurity concentration between a region adjacent to the first surface 100a and a region adjacent to the second surface 100b. For example, the photoelectric conversion regions 110a to 110d may include a plurality of vertically stacked impurity regions.

In embodiments, each of the pixel regions PR may be defined by a pixel separation structure PIS provided in the semiconductor substrate 100. The pixel separation structure PIS may completely or partially penetrate the first surface 100a of the semiconductor substrate 100 in a direction perpendicular to the first surface 100a. The pixel separation structure PIS may penetrate a portion of the device isolation layer 105 adjacent to the first surface 100a of the semiconductor substrate 100.

The pixel separation structure PIS may include first portions extending side by side in the first direction D1 and second portions extending side by side in the second direction D2 across the first portions. Additionally, in each pixel group PG, the pixel separation structure PIS may include a first separation portion P1 disposed between the first and second pixel regions PR1 and PR2, a second separation portion P2 spaced apart from the first separation portion P1 and disposed between the third and fourth pixel regions PR3 and PR4, a third separation portion P3 disposed between the first and third pixel regions PR1 and PR3, and a fourth separation portion P4 spaced apart from the third separation portion P3 and disposed between the second and fourth pixel regions PR2 and PR4. Each of the pixel regions PR may be surrounded by the first to fourth portions P1, P2, P3, and P4 of the pixel separation structure PIS.

According to some embodiments, one floating diffusion region FD may be provided for each pixel group PG. The first and second separation portions P1 and P2 of the pixel separation structure PIS may be spaced apart in the first direction D1 with the floating diffusion region FD interposed therebetween, and the third and fourth separation portions P3 and P4 may be spaced apart from each other in the second direction D2 with the floating diffusion region FD interposed therebetween.

The pixel separation structure PIS may have an upper width at the first surface 100a of the semiconductor substrate 100 and a lower width at the second surface 100b of the semiconductor substrate 100. The lower width may be less than or substantially equal to the upper width. Alternatively, the lower width of the pixel separation structure PIS may be larger than the upper width. For example, the width of the pixel separation structure PIS may gradually decrease from the first surface 100a to the second surface 100b of the semiconductor substrate 100.

The pixel separation structure PIS may have a length in a direction perpendicular to a surface of the semiconductor substrate 100. The length of the pixel separation structure PIS may be substantially equal to a vertical thickness of the semiconductor substrate 100.

The pixel separation structure PIS may be formed by patterning the first surface 100a of the semiconductor substrate 100 to form a deep trench, and then filling the deep trench with multiple layers.

In more detail, referring to FIG. 5, the pixel separation structure PIS may include a sidewall insulating pattern 111, a buried pattern 113, and a capping insulating pattern 115.

The sidewall insulating pattern 111 may be provided between the buried pattern 113 and the semiconductor substrate 100. The sidewall insulating pattern 111 may contact a sidewall of the deep trench formed in the semiconductor substrate 100. The sidewall insulating pattern 111 may include a material having a lower refractive index than the semiconductor substrate 100. The sidewall insulating pattern 111 may be or include, for example, a silicon-based insulating material (e.g., silicon nitride, silicon oxide, and/or or silicon oxynitride) and/or a high dielectric material (e.g., hafnium oxide and/or aluminum oxide). In some embodiments, the sidewall insulating pattern 111 may include a plurality of layers, and the layers may include different materials. The sidewall insulating patterns 111 may have a thickness of approximately 30 Å to 350 Å.

A buried pattern 113 may vertically penetrate a portion of the semiconductor substrate 100. The buried pattern 113 may fill a portion of the deep trench in which the sidewall insulating pattern 111 is formed. The buried pattern 113 may have a different material composition from the sidewall insulating pattern 111. In some embodiments, the buried pattern 113 may include or be formed of a material having a work function that is smaller than that of the semiconductor substrate 100. For example, the work function of the semiconductor substrate 100 may be about 3.7 eV, and the work function of the buried pattern 113 may be 0.1 eV to 3.6 eV. Accordingly, even when no bias is applied to the buried pattern 113, charges may be induced between the buried pattern 113 and the semiconductor substrate 100 due to the work function difference, thereby inducing an interface region 101 (i.e., a depletion region). Additionally, surface defects (e.g., dangling bonds) or thermally generated electron hole pairs (EHP) may be generated in the interface region 101 adjacent to the sidewall of the pixel separation structure PIS.

As an example, when the semiconductor substrate 100 is a silicon substrate doped with impurities of a first conductivity type (e.g., p-type), the buried pattern 113 may include or be an undoped polysilicon layer or a polysilicon layer doped with impurities of a second conductivity (e.g., n-type). An impurity concentration of the second conductivity type in the buried pattern 113 may be lower than that of the second conductivity type in the photoelectric conversion regions 110a, 110b, 110c, and 110d. As another example, when the semiconductor substrate 100 is a silicon substrate, the buried pattern 113 may include silicon germanium (SiGe).

The buried pattern 113 may have, for example, a seam, an air gap, or a void at a center thereof. An upper surface of the buried pattern 113 may be positioned at a different level from the first surface 100a of the semiconductor substrate 100. The upper surface of the buried pattern 113 may be positioned at substantially the same level as a bottom surface of the device isolation layer 105, or may be positioned at a different level, such as at a level above the bottom surface of the device isolation layer 105.

A capping insulating pattern 115 may be disposed on the upper surface of the buried pattern 113, and an upper surface of the capping insulating pattern 115 may be positioned at substantially the same level as an upper surface of the device isolation layer 105. A bottom surface of the capping insulating pattern 115 may be positioned at a higher level (as depicted in FIGS. 4A, 4B, and 5) than the bottom surface of the device isolation layer 105, or may be positioned at the same level.

The bottom surface of the capping insulating pattern 115 may have a rounded shape (e.g., may be concave or convex) or a flat shape. The capping insulating pattern 115 may include or be at least one of a silicon oxide layer, a silicon oxynitride layer, and a silicon nitride layer.

Subsequently, a device isolation layer 105 may be disposed adjacent to the first surface 100a of the semiconductor substrate 100 in each of the pixel regions PR. The device isolation layer 105 may define an active portion on the first surface 100a of the semiconductor substrate 100. The device isolation layer 105 may be provided in a device isolation trench formed by recessing the first surface 100a of the semiconductor substrate 100. The device isolation layer 105 may be formed of an insulating material.

The device isolation layer 105 may overlap a portion of the pixel separation structure PIS. As an example, the device isolation layer 105 may be disposed on the pixel separation structure PIS between adjacent pixel regions PR. The device isolation layer 105 may be disposed adjacent to the first surface 100a of the semiconductor substrate 100.

In each pixel group PG, first to fourth transfer gate electrodes TGa, TGb, TGc, and TGd may be disposed on the first surface 100a of the semiconductor substrate 100.

The first to fourth transfer gate electrodes TGa to TGd may be provided in the first to fourth pixel regions PR1 to PR4, respectively. The first to fourth transfer gate electrodes TGa to TGd may be respectively disposed between the first to fourth photoelectric conversion regions 110a to 110d and the floating diffusion region FD. The first to fourth transfer gate electrodes TGa to TGd may partially overlap the first to fourth photoelectric conversion regions 110a to 110d when viewed in a plan view. The first to fourth transfer gate electrodes TGa to TGd may be disposed in the semiconductor substrate 100. Each of the first to fourth transfer gate electrodes TGa to TGd may include a lower portion inserted into the semiconductor substrate 100 and an upper portion connected to the lower portion and protruding above the first surface 100a of the semiconductor substrate 100. The lower portions of the first to fourth transfer gate electrodes TGa to TGd may vertically penetrate a portion of the semiconductor substrate 100. Bottom surfaces of the first to fourth transfer gate electrodes TGa to TGd may be positioned at a lower level than the first surface 100a of the semiconductor substrate 100.

A gate insulating layer may be interposed between the first to fourth transfer gate electrodes TGa to TGd and the semiconductor substrate 100. The gate insulating layer may be formed of a silicon oxide layer, a silicon oxynitride layer, a high-k dielectric layer having a higher dielectric constant than the silicon oxide layer, or a combination thereof. Source/drain regions of the pixel transistor may include impurities having a second conductivity type. As an example, source/drain regions may include n-type impurities.

A floating diffusion region FD may be provided in common to at least four pixel regions PR. The floating diffusion region FD may be provided in the semiconductor substrate 100 adjacent to the first to fourth transfer gate electrodes TGa to TGd.

The floating diffusion region FD may be formed by ion implanting impurities (e.g., n-type) of the second conductivity type into the semiconductor layer 100 of the semiconductor substrate 100 of the first conductivity type. The floating diffusion region FD may be disposed between the first separation portion P1 and the second separation portion P2 of the pixel separation structure PIS and between the third separation portion P3 and the fourth separation portion P4 of the pixel separation structure PIS.

In each pixel region PR, a ground impurity region GR may be provided in the semiconductor substrate 100 to be spaced apart from each of the first to fourth transfer gate electrodes TGa to TGd. The ground impurity region GR may vertically overlap a portion of each photoelectric conversion region 110a, 110b, 110c, and 110d. The ground impurity region GR may be formed by doping impurities of the same first conductivity type as that of the semiconductor substrate 100. For example, the ground impurity region GR may be a p-type impurity region. The ground impurity region GR may be surrounded by the device isolation layer 105.

A first contact plug 221 may be connected to the ground impurity region GR, and a ground voltage GND may be applied to the first contact plug 221. The ground voltage GND may be applied to the semiconductor substrate 100 through the ground impurity region GR. For example, the first contact plug 221 may be connected to a wiring or switch connected to a ground terminal for connecting to a ground voltage.

According to some embodiments, an inter-pixel impurity region 120 may be provided between the first to fourth photoelectric conversion regions 110a to 110d of the first to fourth pixel regions PR1 to PR4.

The inter-pixel impurity region 120 may vertically overlap the floating diffusion region FD. The inter-pixel impurity region 120 may include impurities of a second conductivity type.

The inter-pixel impurity region 120 may provide an electron movement path between the photoelectric conversion regions 110a to 110d. When photocharges are accumulated in the photoelectric conversion regions 110a to 110d, the inter-pixel impurity region 120 may provide an electron movement path that allows photocharges exceeding a full well capacity (FWC) to flow from one of the photoelectric conversion regions 110a to 110d to another one of the photoelectric conversion regions 110a to 110d. Accordingly, the photocharges may be accumulated by sharing the photoelectric conversion regions 110a to 110d through the inter-pixel impurity region 120 without being affected by spatial limitations of each of the photoelectric conversion regions 110a to 110d.

In addition, a charge drain region PUR may be provided in the semiconductor substrate 100 in each pixel region PR. The charge drain region PUR may be formed by doping the semiconductor substrate 100 with impurities of a second conductivity type opposite to that of the semiconductor substrate 100. The charge drain region PUR may be disposed adjacent to the pixel separation structure PIS to be connected to the interface region 101 between the pixel separation structure PIS and the semiconductor substrate 100. An impurity concentration of the second conductivity type in the charge drain region PUR may be higher than an impurity concentration in the buried pattern 113.

A second contact plug 223 may be connected to the charge drain region PUR, and a pixel power voltage V_{PIX} may be applied to the second contact plug 223, which may be described as a pixel power voltage node. Charges generated in the interface region 101 between the pixel separation structure PIS and the semiconductor substrate 100 may be discharged through the charge drain region PUR. Accordingly, dark current generated by interface defects between the pixel separation structure PIS and the semiconductor substrate 100 may be reduced.

An interlayer insulating layer 210 may cover the transfer gate electrodes TGa, TGb, TGc, and TGd on the first surface 100a of the semiconductor substrate 100. The interlayer insulating layer 210 may include or be formed of, for example, silicon oxide, silicon nitride, and/or silicon oxynitride.

A light transmission layer 30 may be disposed on the second surface 100b of the semiconductor substrate 100. The light transmission layer 30 may include a flat insulating layer 310, a grid structure 320, a protective layer 330, color filters 340, micro lenses 350, and a passivation layer 360. The light transmission layer 30 may collect and filter light incident from the outside and provide the light to the photoelectric conversion circuit layer 10.

In detail, the flat insulating layer 310 may cover the second surface 100b of the semiconductor substrate 100. The flat insulating layer 310 may be formed of a transparent insulating material and may include a plurality of layers. The flat insulating layer 310 may be formed of an insulating material having a refractive index different from that of the semiconductor substrate 100. The flat insulating layer 310 may include metal oxide and/or silicon oxide.

The grid structure 320 may be disposed on the flat insulating layer 310. The grid structure 320 may have a grid shape when viewed in a plan view, like a pixel separation structure PIS. The grid structure 320 may overlap the pixel separation structure PIS when viewed in a plan view. For example, the grid structure 320 may include first portions extending in the first direction D1 and second portions extending in the second direction D2 across the first portions. A width of the grid structure 320 may be substantially equal to or smaller than a minimum width of the pixel separation structure PIS.

The grid structure 320 may include an optical blocking pattern and/or a low refractive index pattern. The optical blocking pattern may include a metal material such as titanium, tantalum, or tungsten, for example. The low refractive pattern may be formed of a material with a lower refractive index than the optical blocking pattern. The low refractive pattern may be formed of an organic material and may have a refractive index of about 1.1 to 1.3. For example, the grid structure 320 may be a polymer layer with silica nanoparticles.

The protective layer 330 may cover a surface of the grid structure 320 on the flat insulating layer 310 with a substantially uniform thickness. The protective layer 330 may include, for example, a single layer or a multilayer of at least one of an aluminum oxide layer and a silicon carbide oxide layer.

The color filters 340 may be formed to correspond to each of the pixel regions PR.

The color filters 340 may fill a space defined by the grid structure 320. The color filters 340 may include red, green, or blue color filters, or magenta, cyan, or yellow color filters, depending on the unit pixel.

The micro lenses 350 may be disposed on the color filters 340. The micro lenses 350 may have a convex shape and a certain radius of curvature. The micro lenses 350 may be formed of light-transmissive resin.

The passivation layer 360 may conformally cover surfaces of the micro lenses 350. The passivation layer 360 may be formed of, for example, an inorganic oxide.

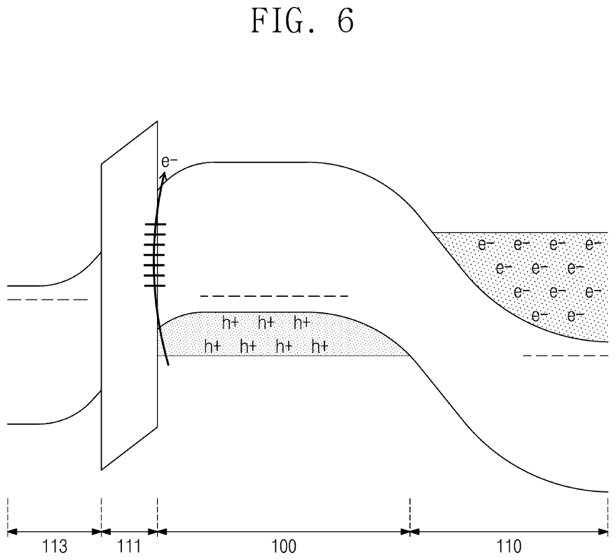

FIG. 6 is an energy band diagram in the cross section A-A′ of FIG. 5.

According to some embodiments, no bias may be applied to the buried pattern 113 of the pixel separation structure PIS, or a certain positive bias may be applied.

Referring to FIG. 6, the energy band between the semiconductor substrate 100 of the first conductivity type (e.g., p-type) and the buried pattern 113 doped with impurities of the second conductivity type (e.g., n-type) may be bent by the work function difference. At the same time, holes may be accumulated and electrons may be generated in the interface region 101 (or the depletion region) between the sidewall insulating pattern 111 and the semiconductor substrate 100 due to Shockley-read-hall (SRH) recombination. Accordingly, the pixel power voltage V_{PIX} may be applied through the charge drain region PUR so that electrons generated in the interface region 101 may be discharged.

The electrons generated in the interface region 101 may be discharged through the charge drain region PUR to which a positive bias is applied. Accordingly, dark current generated by interface defects between the pixel separation structure PIS and the semiconductor substrate 100 may be reduced.

When no bias is applied to the buried pattern 113 and the buried pattern 113 is in an electrically floating state, the energy band may bend due to the work function difference between the semiconductor substrate 100 and the buried pattern 113, and the interface region 101 (or the depletion region) may be formed between the sidewall insulating pattern 111 and the semiconductor substrate 100. In this example, in one embodiment, the buried pattern 113 may be floating due to being isolated by insulating layers.

A certain positive bias or ground voltage may be applied to the buried pattern 113, and in this case, a width of the interface region 101 (or the depletion region) may increase further compared to when a bias is not applied to the buried pattern 113. For example, during operation, the buried pattern 113 may be selectively connected between a ground voltage node (e.g., a node connected to ground), a positive bias voltage node (e.g., a node connected to receive a positive bias voltage), or a floating state, for example using one or more switches.

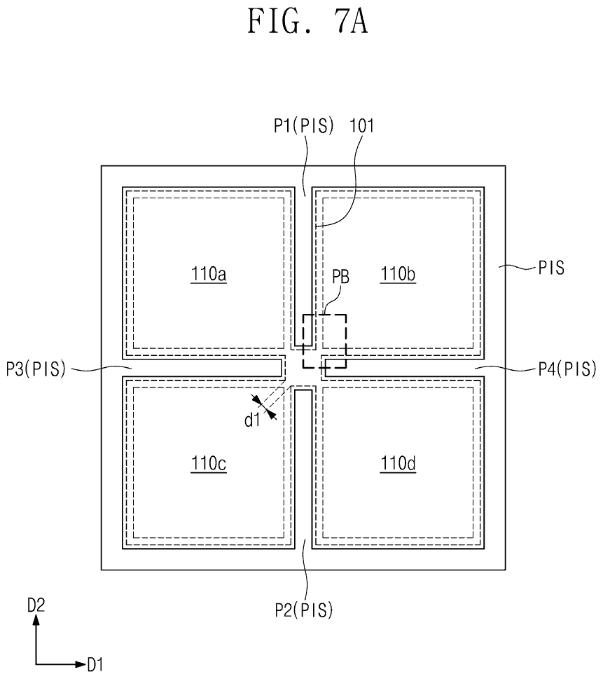

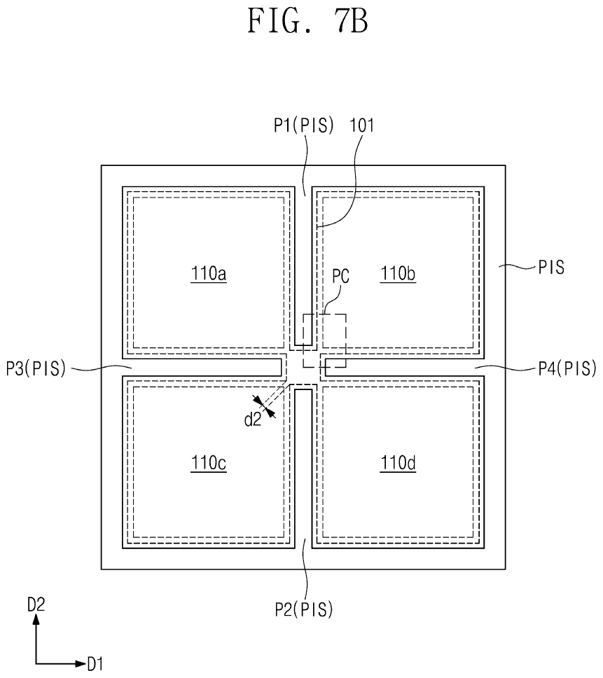

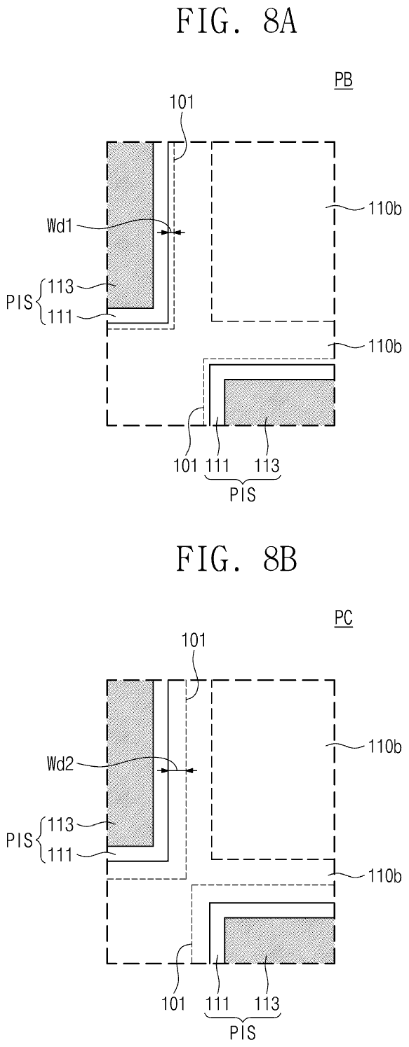

FIG. 7A is a plan view showing a portion of an image sensor according to embodiments of the inventive concept. FIG. 7B is a plan view showing a portion of an image sensor according to embodiments of the inventive concept. FIG. 8A is an enlarged view of portion ‘PB’ of FIG. 7A. FIG. 8B is an enlarged view of portion ‘PC’ of FIG. 7B. For simplicity of explanation, description of the same technical features as the image sensor described above may be omitted.

According to some embodiments, a level of potential barrier between the first to fourth photoelectric conversion regions 110a to 110d may be adjusted by controlling the voltage applied to the buried pattern 113 of the pixel separation structure PIS. For example, the full well capacity (FWC) of adjacent photoelectric conversion regions may be adjusted depending on an operation mode of the image sensor.

In detail, as shown in FIGS. 7A and 7B, when no bias is applied to the buried pattern 113, for example, when the buried pattern 113 is electrically floating, the depletion region 101 induced between the pixel separation structure PIS and the semiconductor substrate 100 may have a first width Wd1. In addition, when no bias is applied to the buried pattern 113, adjacent interface regions 101 may be spaced apart by a first distance d1 in a diagonal direction with respect to the first and second directions D1 and D2.

Referring to FIGS. 8A and 8B, a certain positive bias may be applied to the buried pattern 113 doped with n-type impurities, and accordingly, a width of the interface region 101 (or the depletion region) between the sidewall insulating pattern 111 and the semiconductor substrate 100 may be increased.

When a certain positive bias is applied to the buried pattern 113, as shown in FIGS. 8A and 8B, the depletion region 101 induced between the pixel separation structure PIS and the semiconductor substrate 100 may have a second width Wd2 that is larger than the first width Wd1. In addition, when a certain positive bias is applied to the buried pattern 113, adjacent interface regions 101 may be spaced apart by a second distance d2 that is smaller than the first distance d1 in a diagonal direction with respect to the first and second directions D1 and D2.

When the positive bias is applied to the buried pattern 113, a potential level between the first to fourth separation portions P1 to P4 in the pixel separation structure PIS in a diagonal direction with respect to the first and second directions D1 and D2 may be lower than when a bias is not applied thereto. For example, a potential barrier between adjacent first to fourth photoelectric conversion regions 110a to 110d may be lowered.

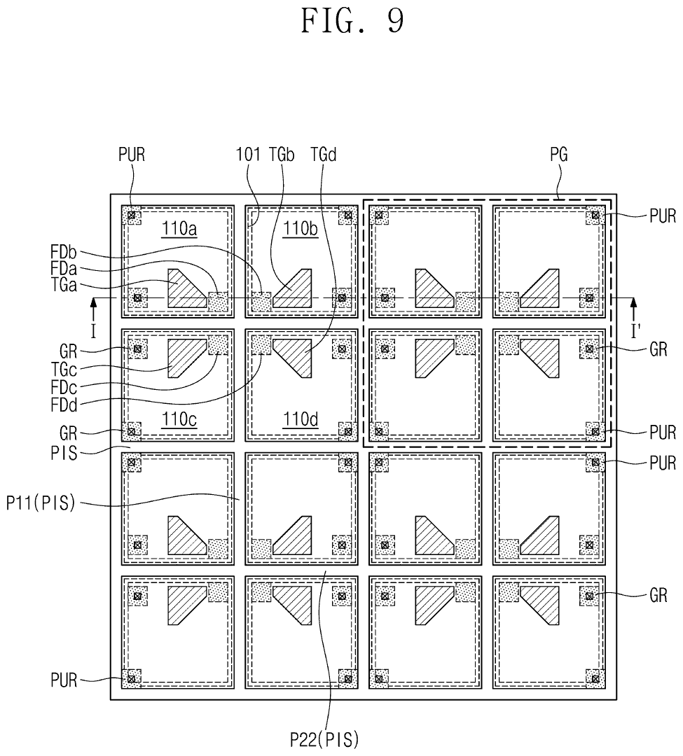

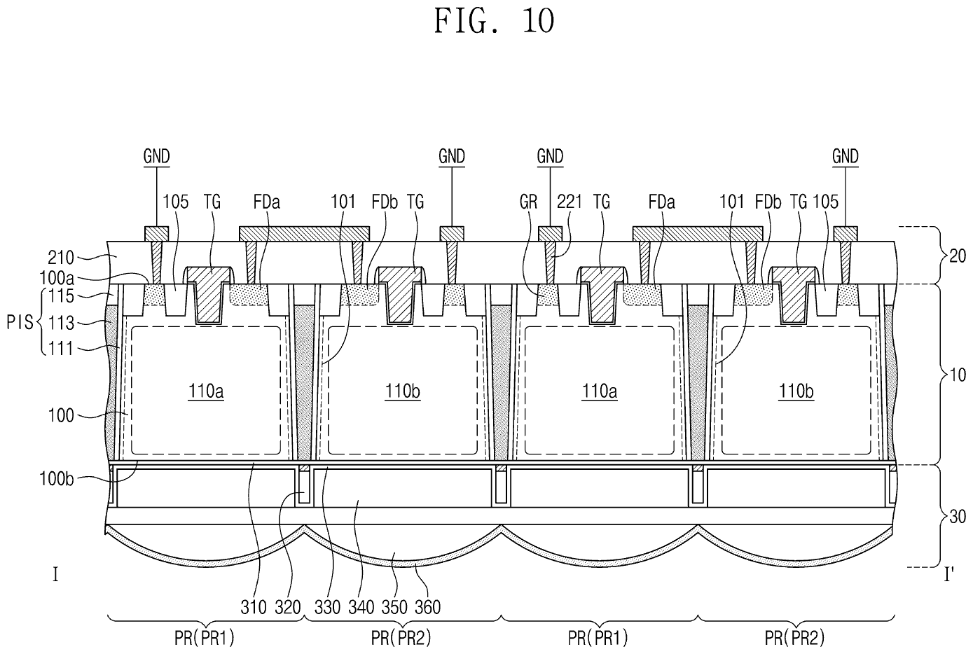

FIG. 9 is a plan view showing a portion of an image sensor according to embodiments of the inventive concept. FIG. 10 is a cross-sectional view of an image sensor according to embodiments of the inventive concept, taken along line I-I′ of FIG. 9. For simplicity of explanation, description of the same technical features as the image sensor described above may be omitted.

Referring to FIGS. 9 and 10, the pixel separation structure PIS may include first portions P11 extending parallel to each other in the first direction D1 and second portions P22 extending parallel to each other in the second direction across the first portions P11. The pixel separation structure PIS may completely surround each of the pixel regions PR when viewed in a plan view.

First to fourth floating diffusion regions FDa, FDb, FDc, and FDd may be provided in the first to fourth pixel regions PR1 to PR4, respectively. The first to fourth floating diffusion regions FDa to FDd may be provided in the semiconductor substrate 100 on one side of the first to fourth transfer gate electrodes TGa to TGd. The first to fourth floating diffusion regions FDa to FDd may vertically overlap a portion of the first to fourth photoelectric conversion regions 110a to 110d.

According to some embodiments, the first to fourth floating diffusion regions FDa to FDd may be electrically connected to each other through contact plugs and wirings.

Furthermore, in each pixel region PR, a charge drain region PUR may be provided in the semiconductor substrate 100 to be adjacent to the pixel separation structure PIS. In each of the pixel regions PR, charges due to surface defects are accumulated between the buried pattern 113 of the pixel separation structure PIS and the semiconductor substrate 100 to form an interface region 101. In each of the pixel regions PR, charges accumulated in the interface region 101 may be discharged through the charge drain region PUR.

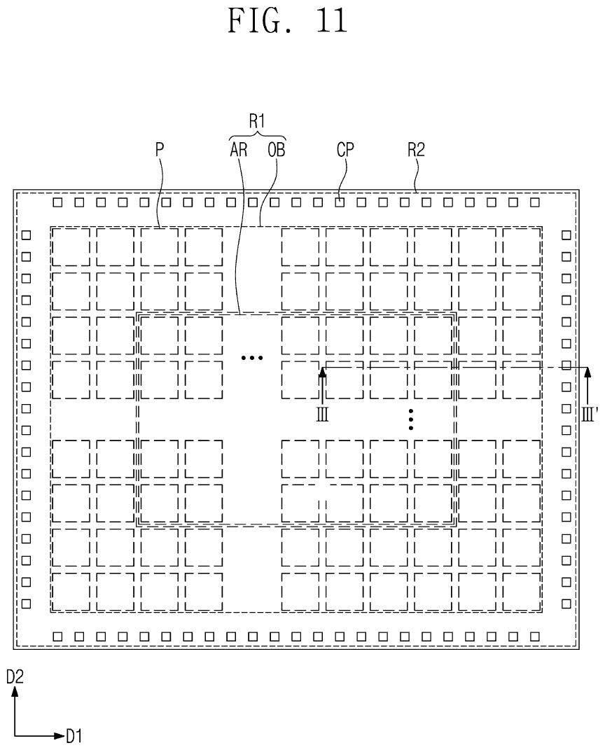

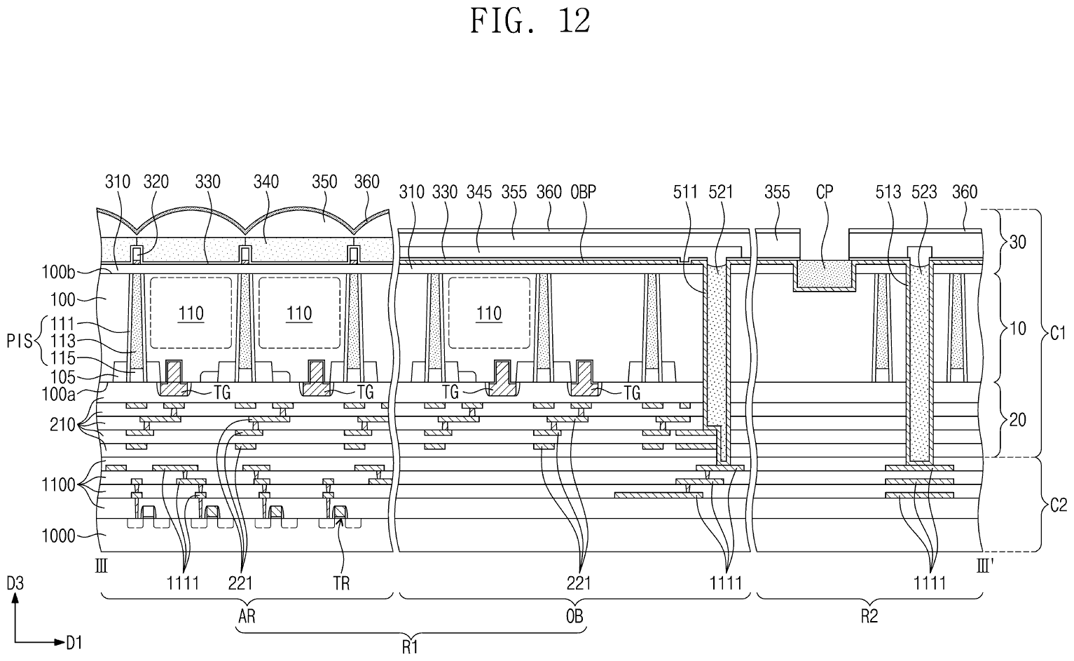

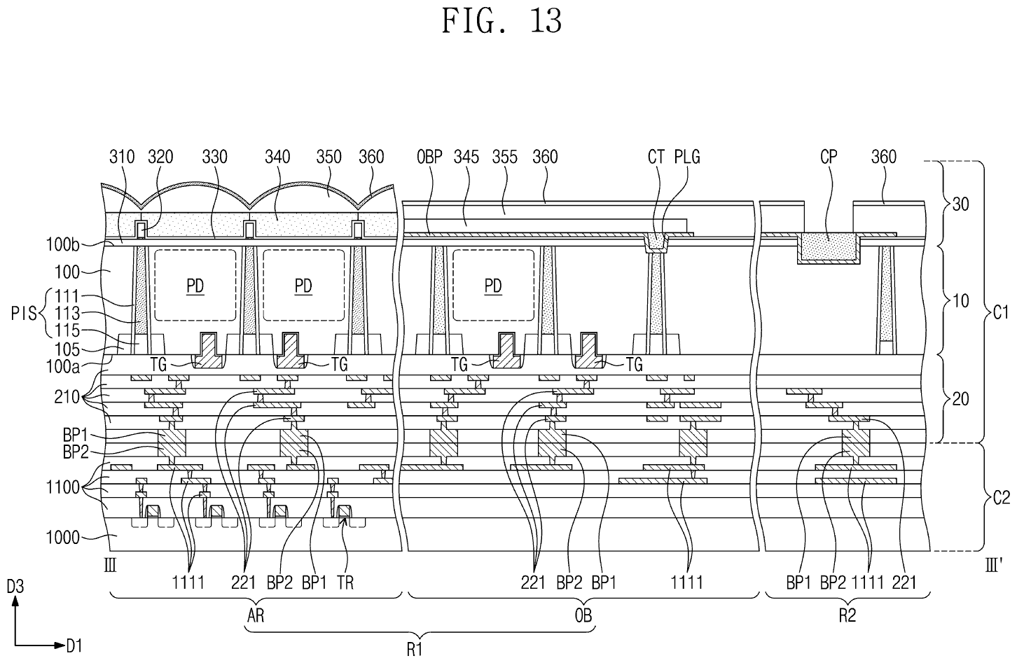

FIG. 11 is a schematic plan view of an image sensor including a semiconductor device according to embodiments of the inventive concept. FIGS. 12 and 13 are cross-sectional views of an image sensor according to embodiments of the inventive concept, showing a cross-section taken along line III-III′ of FIG. 11.

Referring to FIGS. 11 and 12, an image sensor may include a sensor chip C1 and a logic chip C2. The sensor chip C1 may include a pixel array region R1 and a pad region R2.

The pixel array region R1 may include a plurality of unit pixels P arranged two-dimensionally in first and second directions D1 and D2 that intersect each other. Each of the unit pixels P may include a photoelectric conversion element and a readout element. An electrical signal generated by incident light may be output from each of the unit pixels P of the pixel array region R1.

The pixel array region R1 may include a light receiving region AR and an optical blocking region OB. The optical blocking region OB may surround the light receiving region AR when viewed in a two-dimensional perspective view. The optical blocking region OB may be arranged above, below, and to the left and right of the light receiving region AR when viewed in a planar perspective view. Reference pixels on which no light is incident may be provided in the optical blocking region OB, and the amount of charge sensed by the unit pixels P in the light receiving region AR may be compared with a reference amount of charge generated in the reference pixels to calculate the size of electrical signal detected in the unit pixels P.

A plurality of conductive pads CP used to input and output control signals, photoelectric signals, etc. may be disposed in the pad region R2. The pad region R2 may surround the pixel array region R1 when viewed in a plan view to facilitate electrical connection with external devices. The conductive pads CP may input and output electrical signals generated from the unit pixels P to an external device.

The sensor chip C1 in the light receiving region AR may include the same technical features as the image sensor described above. For example, as described above, the sensor chip C1 may include the photoelectric conversion circuit layer 10 between the pixel circuit layer 20 and the light transmission layer 30 in a vertical direction. As described above, the photoelectric conversion circuit layer 10 of the sensor chip C1 may include a semiconductor substrate 100, a pixel separation structure PIS defining pixel regions, and photoelectric conversion regions PD provided in the pixel regions. The pixel separation structure PIS may have substantially the same structure in the light receiving region AR and the optical blocking region OB.

The light transmission layer 30 may include an optical blocking pattern OBP, an organic layer 355, and a passivation layer 360 in the optical blocking region OB. In some embodiments, the pixel separation structure PIS may continuously extend from the light receiving region AR to the optical blocking region OB, and the buried pattern 113 of the pixel separation structure PIS may be electrically connected without being connected to a conductive plug or may be applied with a ground voltage.

In the optical blocking region OB, an optical blocking pattern OBP may be disposed on an upper surface of the flat insulating layer 310. The optical blocking pattern OBP may include the same material as the conductive pattern of the grid structure 320 in the light receiving region AR. That is, the optical blocking pattern OBP may include a metal pattern and a metal oxide pattern. For example, the optical blocking pattern OBP may include titanium nitride and titanium oxynitride. The optical blocking pattern OBP may not extend to the light receiving region AR.

The optical blocking pattern OBP may block light from being incident on the photoelectric conversion regions PD provided in the optical blocking region OB. The photoelectric conversion regions PD in the reference pixel regions of the optical blocking region OB may not output a photoelectric signal but may output a noise signal. The noise signal may be generated by electrons generated by heat generation or dark current.

A protective layer 330 may extend from the pixel array region R1 to the pad region R2. The protective layer 330 may cover an upper surface of the optical blocking pattern OBP.

A filtering layer 345 may cover the protective layer 330 in the optical blocking region OB. The filtering layer 345 may block light of a different wavelength from color filters 340. For example, the filtering layer 345 may block infrared rays. The filtering layer 345 may include a blue color filter, but is not limited thereto.

An organic layer 355 and a passivation layer 360 may be provided on the protective layer 330 in the optical blocking region OB and the pad region R2. The organic layer 355 may include the same material as the micro lenses 350.

In the optical blocking region OB, the first through conductive pattern 511 may penetrate the semiconductor substrate 100 and be electrically connected to a metal wiring of the pixel circuit layer 20 and a wiring structure 1111 of the logic chip C2. A first through conductive pattern 511 may have a first bottom surface and a second bottom surface positioned at different levels. A first buried pattern 521 may be provided inside the first through conductive pattern 511. The first buried pattern 521 may include a low refractive index material and may have insulating characteristics.

In the pad region R2, conductive pads CP may be provided on the second surface 100b of the semiconductor substrate 100. Conductive pads CP may be buried in the second surface 100b of the semiconductor substrate 100. As an example, the conductive pads CP may be provided in a pad trench formed on the second surface 100b of the semiconductor substrate 100 in the pad region R2. The conductive pads CP may include metal such as aluminum, copper, tungsten, titanium, tantalum, or alloys thereof. In the image sensor mounting process, a bonding wire may be bonded to the conductive pads CP. The conductive pads CP may be electrically connected to an external device through a bonding wire.

In the pad region R2, a second through conductive pattern 513 may penetrate the semiconductor substrate 100 and be electrically connected to the wiring structure 1111 of the logic chip C2. The second through conductive pattern 513 may extend onto the second surface 100b of the semiconductor substrate 100 and be electrically connected to the conductive pads CP. A portion of the second through conductive pattern 513 may cover a bottom surface and sidewalls of the conductive pads CP. A second buried pattern 523 may be provided inside the second through conductive pattern 513. The second buried pattern 523 may include a low refractive index material and may have insulating characteristics. In the pad region R2, pixel separation structures PIS may be provided around the second through conductive pattern 513.

The logic chip C2 may include a logic semiconductor substrate 1000, logic circuits TR, interconnection structures 1111 connected to the logic circuits TR, and logic interlayer insulating layers 1100. The uppermost layer of the logic interlayer insulating layers 1100 may be bonded to the pixel circuit layer 20 of the sensor chip C1. The logic chip C2 may be electrically connected to the sensor chip C1 through the first through conductive pattern 511 and the second through conductive pattern 513.

In one example, it has been described that the sensor chip C1 and the logic chip C2 are electrically connected to each other through the first and second through conductive patterns 511 and 513, but the inventive concept is not limited thereto.

According to the embodiment shown in FIG. 13, the first and second through conductive patterns shown in FIG. 12 may be omitted, and the bonding pads provided on the uppermost meal layer of the sensor chip C1 and the logic chip C2 may be directly bonded (e.g., using hybrid bonding), thereby electrically bonding the sensor chip C1 and the logic chip C2.

In detail, in the sensor chip C1, the buried pattern 113 of the pixel separation structure PIS extending from the light receiving region AR to the optical blocking region OB may be connected to a backside contact plug PLG in the optical blocking region OB. Accordingly, a certain amount of bias may be applied to the buried pattern 113. The backside contact plug PLG may have a width greater than a width of the pixel separation structure PIS. The backside contact plug PLG may include metal and/or metal nitride. For example, the backside contact plug PLG may include titanium and/or titanium nitride.

A contact pattern CT may be buried in a contact hole where the backside contact plug PLG is formed. The contact pattern CT may include a different material than the backside contact plug PLG. For example, the contact pattern CT may include aluminum (Al).

The contact pattern CT and the backside contact plug PLG may be electrically connected to the buried pattern 113 of the pixel separation structure PIS. A positive bias may be applied to the buried pattern 113 of the pixel separation structure PIS through the contact pattern CT, and the positive bias may be transferred from the optical blocking region OB to the light receiving region AR. Accordingly, dark current occurring at the interface between the pixel separation structure PIS and the semiconductor substrate 100 may be reduced.

In addition, the sensor chip C1 may include first bonding pads BP1 provided on the uppermost metal layer of the pixel circuit layer 20, and the logic chip C2 may include second bonding pads BP2 provided on the uppermost metal layer of the wiring structure 1111. The first and second bonding pads BP1 and BP2 may include at least one of, for example, tungsten (W), aluminum (Al), copper (Cu), tungsten nitride (WN), tantalum nitride (TaN), and titanium nitride (TiN).

The first bonding pads BP1 of the sensor chip C1 and the second bonding pads BP2 of the logic chip C2 may be directly electrically and physically connected to each other using a hybrid bonding method. The hybrid bonding refers to bonding in which two components containing the same type of material fuse at their interface. For example, when the first and second bonding pads BP1 and BP2 are formed of copper (Cu), the first and second bonding pads BP1 and BP2 may be physically and electrically connected by copper (Cu)-copper (Cu) bonding. Additionally, a surface of an insulating layer of the sensor chip C1 and a surface of an insulating layer of the logic chip C2 may be bonded by dielectric-dielectric bonding.

According to embodiments of the inventive concept, the certain positive bias may be applied to the buried pattern of the pixel separation structure, and thus the voltage difference between the voltage nodes (e.g., the pixel voltage node (or ground voltage node) and the negative voltage node) may be reduced.

The potential barrier level between photoelectric conversion regions may be adjusted by controlling the voltage applied to the buried pattern. Therefore, the full well capacity (FWC) of adjacent photoelectric conversion regions may be adjusted depending on the operation mode of the image sensor.

The electrons generated in the interface region between the pixel separation structure and the semiconductor substrate may be discharged through the charge drain region to which the positive bias is applied. Accordingly, the dark current generated by interface defects between the pixel separation structure and the semiconductor substrate may be reduced.

While embodiments are described above, a person skilled in the art may understand that many modifications and variations are made without departing from the spirit and scope of the inventive concept defined in the following claims. Accordingly, the example embodiments of the inventive concept should be considered in all respects as illustrative and not restrictive, with the spirit and scope of the inventive concept.

What is claimed is:

1. An image sensor comprising:
a semiconductor substrate of a first conductivity type including a plurality of pixel regions;
a pixel separation structure disposed between the pixel regions and vertically penetrating the semiconductor substrate, the pixel separation structure including a buried pattern and a sidewall insulating pattern between a sidewall of the buried pattern and the semiconductor substrate;
photoelectric conversion regions respectively provided in the pixel regions and including impurities of a second conductivity type; and
a charge drain region of the second conductivity type provided in the semiconductor substrate, the charge drain region contacting an interface region between the sidewall insulating pattern and the semiconductor substrate,
wherein the buried pattern includes a semiconductor material doped with impurities of the second conductivity type.

2. The image sensor of claim 1, wherein the buried pattern is connected to receive a ground voltage or a positive bias voltage.

3. The image sensor of claim 1, wherein the buried pattern includes a material having a work function smaller than that of the semiconductor substrate.

4. The image sensor of claim 1, wherein the buried pattern is configured to be electrically floating.

5. The image sensor of claim 1, wherein the pixel regions include first and second pixel regions arranged in a first direction, a third pixel region adjacent to the first pixel region in a second direction intersecting the first direction, and a fourth pixel region adjacent to the second pixel region in the second direction, and
wherein the charge drain region is provided in one of the first to fourth pixel regions.

6. The image sensor of claim 5, further comprising:
a floating diffusion region provided in the semiconductor substrate and including impurities of the second conductivity type; and
transfer gate electrodes disposed between the photoelectric conversion regions and the floating diffusion region,
wherein the floating diffusion region is commonly provided between the first to fourth pixel regions.

7. The image sensor of claim 5, wherein the pixel separation structure includes:
a first separation portion disposed between the first and second pixel regions;
a second separation portion spaced apart from the first separation portion and disposed between the third and fourth pixel regions;
a third separation portion disposed between the first and third pixel regions; and
a fourth separation portion spaced apart from the third separation portion and disposed between the second and fourth pixel regions, and
wherein a floating diffusion region is disposed between the first separation portion and the second separation portion, and between the third separation portion and the fourth separation portion.

8. The image sensor of claim 5, further comprising an inter-pixel impurity region provided between the photoelectric conversion regions of the first to fourth pixel regions and including impurities of the second conductivity type.

9. The image sensor of claim 5, further comprising a ground impurity region of the first conductivity type disposed in the semiconductor substrate in each of the first to fourth pixel regions.

10. An image sensor comprising:
a semiconductor substrate of a first conductivity type;
a pixel separation structure disposed in the semiconductor substrate and defining a pixel region, the pixel separation structure including a buried pattern and a sidewall insulating pattern between a sidewall of the buried pattern and the semiconductor substrate; and
a photoelectric conversion region of a second conductivity type provided in the semiconductor substrate of the pixel region,
wherein, in the pixel separation structure, the buried pattern includes a material having a work function smaller than that of the semiconductor substrate.

11. The image sensor of claim 10, wherein the buried pattern includes a semiconductor material doped with impurities of the second conductivity type.

12. The image sensor of claim 10, wherein the buried pattern is connected to receive a ground voltage.

13. The image sensor of claim 10, further comprising a charge drain region disposed in the semiconductor substrate and connected to an interface region configured to include charges induced between the sidewall insulating pattern and the semiconductor substrate.

14. The image sensor of claim 13, wherein the charge drain region is connected to a pixel power voltage node.

15. The image sensor of claim 13, wherein the buried pattern is connected to receive a positive bias.

16. The image sensor of claim 13, wherein the buried pattern is electrically floating.

17. The image sensor of claim 10, further comprising:
a floating diffusion region provided in the semiconductor substrate in the pixel region and including impurities of the second conductivity type; and
a transfer gate electrode disposed on the semiconductor substrate between the photoelectric conversion region and the floating diffusion region.

18. An image sensor comprising:
a semiconductor substrate of a first conductivity type having first and second surfaces facing away from each other;
a pixel separation structure disposed in the semiconductor substrate and defining a plurality of pixel regions, the pixel separation structure including a buried pattern including a semiconductor material doped with impurities of a second conductivity type, and a sidewall insulating pattern between a sidewall of the buried pattern and the semiconductor substrate;
a charge drain region of the second conductivity type in contact with an interface region between the sidewall insulating pattern and the semiconductor substrate in the semiconductor substrate;
photoelectric conversion regions provided in each of the pixel regions and including impurities of the second conductivity type;
a floating diffusion region having impurities of the second conductivity type provided in the semiconductor substrate;
transfer gate electrodes disposed between the photoelectric conversion regions and the floating diffusion region;
a ground impurity region provided in each of the pixel regions and including impurities of the first conductivity type;
a plurality of micro lenses disposed on the second surface of the semiconductor substrate and provided respectively in the pixel regions; and
color filters disposed between the micro lenses and the second surface of the semiconductor substrate and provided to each of the pixel regions.

19. The image sensor of claim 18, wherein the charge drain region is configured to receive a pixel power voltage, and
wherein the buried pattern is configured to be electrically floating or to have a ground voltage applied thereto.

20. The image sensor of claim 18, wherein the charge drain region is configured to receive a pixel power voltage and the buried pattern is configured to receive a positive bias.
